(19) United States
(12) Patent Application Publication
(10) Pub. No.: US 2014/0159061 A1
(43) Pub. Date: Jun. 12, 2014

(54) PROTECTION ELEMENT AND LIGHT EMITTING DEVICE USING SAME

(71) Applicants: Naoya Tomoda, Kyoto (JP); Yoshiyuki Norimitsu, Kagoshima (JP); Koichi Nakahara, Kagoshima (JP)

(72) Inventors: Naoya Tomoda, Kyoto (JP); Yoshiyuki Norimitsu, Kagoshima (JP); Koichi Nakahara, Kagoshima (JP)

(73) Assignee: PANASONIC CORPORATION, Osaka (JP)

(21) Appl. No.: 14/234,956

(22) PCT Filed: Aug. 24, 2012
(86) PCT No.: PCT/JP2012/005313

§ 371 Date: Jan. 24, 2014

(30) Foreign Application Priority Data
Aug. 25, 2011 (JP) 2011-183273

(51) Int. Cl. H01L 33/48; H01L 23/60

(52) U.S. Cl. CPC H01L 33/48; H01L 23/60
USPC 257/79

(57) ABSTRACT

A protective element includes a semiconductor substrate, connecting electrodes, bottom electrodes, and a protection circuit. The connecting electrodes are provided on a mount surface of the semiconductor substrate on which a light-emitting element for flip-chip mounting is mounted so as to be each connected to an electrode of the light-emitting element. The protection circuit is provided in the semiconductor substrate so as to be connected through the connecting electrodes to the light-emitting element. The bottom electrodes are provided on a surface of the semiconductor substrate opposite to the mount surface, are each connected to a corresponding one of the connecting electrodes, and are configured so as to be each connected to an electrode on the mounting base.

### TECHNICAL FIELD

The present disclosure relates to protective elements on each of which a light-emitting element is placed, and each of which is connected to the light-emitting element in parallel to protect the light-emitting element from high voltages, such as static electricity, and light-emitting devices including the same.

### BACKGROUND ART

Since light-emitting elements consume lower current, have a longer life, and is more compact in size than electric bulbs and fluorescent lamps, demands for such elements serving as alternative light sources to electric bulbs and fluorescent lamps have been increasing.

Applying a high reverse voltage to a light-emitting element causes a breakdown of the light-emitting element. Thus, the light-emitting element may be connected to a protective element.

For example, a conventional light-emitting device includes a light-emitting element and a Zener diode that is an example protective element. The light-emitting element and the Zener diode are laterally arranged on an element mount surface of a printed wiring board, and are encapsulated with an encapsulation resin. The light-emitting device includes the printed wiring board having a conductor pattern that connects the light-emitting element and the Zener diode in parallel.

A protective element described in PATENT DOCUMENT 1 has been known. PATENT DOCUMENT 1 describes a composite light-emitting element including a flip-chip mounted light-emitting element and a submount element (a Si diode element) that is a protective element. The flip-chip mounted light-emitting element is placed on the submount element with Au microbumps interposed therebetween to be electrically continuous with the submount element, and the light-emitting element is covered with a resin containing a fluorescent material. A p-type semiconductor region of the Si diode element includes a p electrode connected to the light-emitting element and including a bonding pad connected to a wire. An n-type semiconductor region of the Si diode element includes an n electrode connected to the light-emitting element. A back electrode is connected to the n-type semiconductor region.

The composite light-emitting element is placed on, for example, an external member having an insulative substrate including a lead. The composite light-emitting element is connected through the back electrode to the external member, and is connected through the wire and the bonding pad to the external member.

### CITATION LIST

### Patent Document

PATENT DOCUMENT 1: Japanese Unexamined Patent Publication No. 2001-15817

### SUMMARY OF THE INVENTION

### Technical Problem

However, in the conventional light-emitting device including the light-emitting element and the protective element arranged on the printed wiring board, the protective element blocks the travel of light from the light-emitting element to disable uniform irradiation of a surrounding region with the light from the light-emitting element.

Since, in the light-emitting device described in PATENT DOCUMENT 1, the light-emitting element is connected through the wire to the external member, the wire blocks the travel of the light from the light-emitting element to disable uniform irradiation of a surrounding region with the light from the light-emitting element. Furthermore, the light-emitting element and the wire need to be encapsulated with a resin to protect the wire. This prevents the light-emitting device from being downsized, requires time and effort to manufacture the light-emitting device, and increases cost.

The present disclosure, therefore, can provide a protective element that protects a light-emitting element, enables uniform irradiation of a surrounding region with light from the light-emitting element, and can be downsized, and a light-emitting device including the same.

### SOLUTION TO THE PROBLEM

A protective element according to an aspect of the present disclosure includes: a semiconductor substrate; connecting electrodes provided on a mount surface of the semiconductor substrate on which a flip-chip mounted light-emitting element is mounted so as to be connected to an electrode of the light-emitting element, a protection circuit provided in the semiconductor substrate so as to be connected through the connecting electrodes to the flip-chip mounted light-emitting element; and bottom electrodes provided on a surface of the semiconductor substrate opposite to the mount surface, each connected to a corresponding one of the connecting electrodes, and configured so as to be each connected to an electrode on a mounting base.

### ADVANTAGES OF THE INVENTION

The protective element of the present disclosure does not require wiring, thereby eliminating the need for entirely encapsulating a wired device including the semiconductor substrate and the protective element after the wiring. This elimination allows the protective element including the light-emitting element to be treated as a single light-emitting device. Thus, the protective element of the present disclosure protects the light-emitting element, enables uniform irradiation of a surrounding region with light from the light-emitting element, and can be downsized.

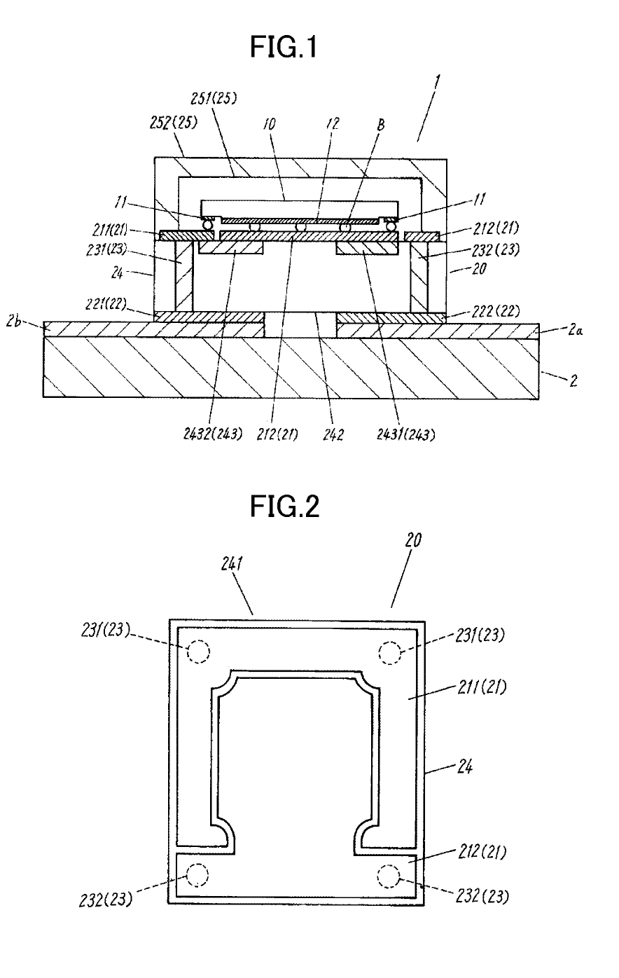

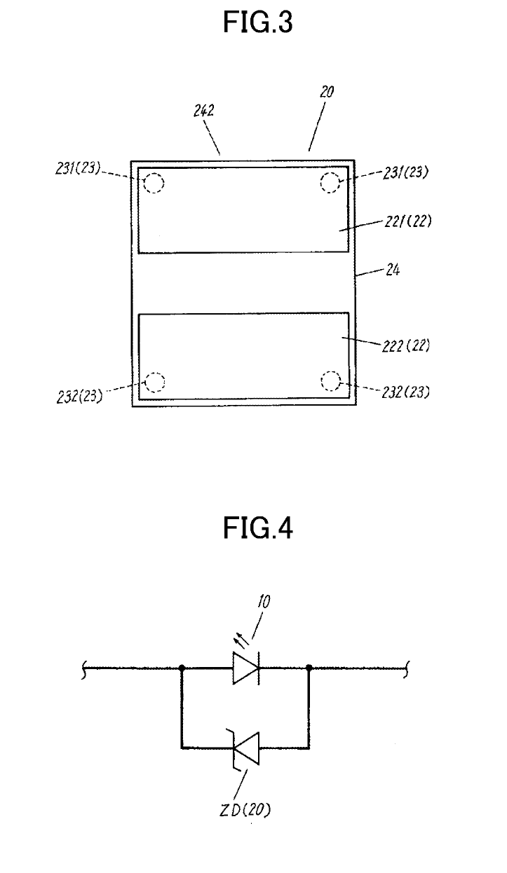

### BRIEF DESCRIPTION OF THE DRAWINGS

[FIG. 1] FIG. 1 is a cross-sectional view illustrating a light-emitting device according to an embodiment.

[FIG. 2] FIG. 2 is a plan view illustrating a protective element of the light-emitting device illustrated in FIG. 1.

[FIG. 3] FIG. 3 is a bottom view illustrating the protective element illustrated in FIG. 2.

[FIG. 4] FIG. 4 illustrates a circuit configuration of the light-emitting device illustrated in FIG. 1.

### DESCRIPTION OF EMBODIMENTS

An example protective element includes: a semiconductor substrate; connecting electrodes provided on a mount surface of the semiconductor substrate on which a light-emitting element for flip-chip mounting is mounted so as to be connected to an electrode of the light-emitting element, a protection circuit provided in the semiconductor substrate so as to be connected through the connecting electrodes to the light-emitting element; and bottom electrodes provided on a surface of the semiconductor substrate opposite to the mount surface, each connected to a corresponding one of the connecting electrodes, and configured so as to be each connected to an electrode on a mounting base.

According to the example protective element, the light-emitting element is mounted on the semiconductor substrate including the protection circuit with the connecting electrodes, which are provided on the mount surface, interposed between the light-emitting element and the semiconductor substrate. This can prevent the protection circuit from blocking the travel of light from the light-emitting element. The protective element can be connected through the bottom electrodes to the mounting base so as to be electrically continuous with the mounting base, thereby preventing a wire from blocking the travel of light from the light-emitting element. The example protective element does not require wiring, thereby eliminating the need for entirely encapsulating a wired device after the wiring. This elimination allows the protective element including the light-emitting element to be treated as a single light-emitting device.

The example protective element may further include: through-hole electrodes each connecting a corresponding one of the connecting electrodes to a corresponding one of the bottom electrodes.

When the connecting electrodes are each connected to a corresponding one of the bottom electrodes through a corresponding one of the through-hole electrodes, a plurality of protection circuits are formed in the surface of a wafer, the connecting electrodes, the bottom electrodes, and the through-hole electrodes all corresponding to each of the protection circuits are then formed at the wafer level, and the wafer is diced to obtain many protective elements.

In the example protective element, the semiconductor substrate may be a silicon substrate.

The silicon substrate tends to be flatter than, for example, a ceramic substrate, and when the light-emitting element is mounted on the silicon substrate, the optical axis is less likely to be misaligned.

In the example protective element, the protection circuit can include a Zener diode, a diode, or a varistor.

With such a configuration, the light-emitting element can be appropriately protected.

An example light-emitting device includes: the example protective element; the light-emitting element incorporated into the protective element; and a resin encapsulating part that contains a fluorescent material excited by light from the light-emitting element to emit light, and encapsulates the light-emitting element.

According to the example light-emitting device, the light-emitting element is encapsulated with the resin encapsulating part containing the fluorescent material excited by the light from the light-emitting element to emit light, thereby protecting the light-emitting element and providing a light-emitting device emitting light of various colors obtained by mixing the color of light emitted from the light-emitting element and the color of light emitted from the fluorescent material.

### Embodiment

A protective element and a light-emitting device according to an embodiment will be described with reference to the drawings. Examples of a light-emitting device 1 can include a lighting device for an electronic flash of a mobile phone as illustrated in FIG. 1. The light-emitting device 1 is mounted on power-source-supplying interconnect traces 2a and 2b on a mounting substrate (mounting base) 2 incorporated into, for example, a mobile phone with a conductive adhesive, such as solder, interposed between the light-emitting device 1 and the interconnect traces 2a and 2b to be electrically continuous with the interconnect traces 2a and 2b.

As illustrated in FIGS. 1-3, the light-emitting device 1 includes a light-emitting element 10 and a protective element 20.

The light-emitting element 10 is a flip-chip mounted light-emitting diode (LED) including semiconductor layers stacked on an optically transparent substrate, and electrodes configured to supply a power source. The light-emitting element 10 can be, for example, an LED emitting blue light.

In this embodiment, a GaN substrate is provided as the optically transparent substrate. An n-GaN layer that is an n-type layer, a light-emitting layer, and a p-GaN layer that is a p-type layer are stacked, as the semiconductor layers, on the GaN substrate. A buffer layer may be provided between the GaN substrate and the n-GaN layer. For example, Si or Ge is suitable for use as an n-type dopant for the n-GaN layer. The light-emitting layer contains at least Ga and N, and contains an appropriate amount of In as necessary to obtain a desired emission wavelength. While the light-emitting layer can have a single-layer structure, the light-emitting layer can have a multiple quantum well structure including, for example, at least one pair of an InGaN layer and a GaN layer that are alternately stacked. The light emitting layer having a multiple quantum well structure can further improve brightness. While the light-emitting element 10 of this embodiment is an LED that does not have an optical waveguide, it may be, for example, a laser diode or a superluminescent diode having an optical waveguide,

The p-GaN layer is placed directly on the light-emitting layer, or placed on the light-emitting layer with a semiconductor layer that contains at least Ga and N interposed therebetween. For example, Mg is suitable for use as a p-type dopant for the p-GaN layer.

A cathode electrode 11 and an anode electrode 12 are formed on a group of the semiconductor layers. The cathode electrode 11 is an n electrode provided on an exposed region of the n-GaN layer remaining after the p-GaN layer, the light-emitting layer, and the n-GaN layer have been etched. The cathode electrode 11 includes an Al layer, a Ti layer, and an Au layer that are stacked.

The anode electrode 12 is a p electrode placed on a region of the p-GaN layer remaining after the etching. The anode electrode 12 includes a Ni layer and an Ag layer that are stacked. The anode electrode 12 includes the Ag layer exhibiting high reflectivity, and thus, functions as a reflective electrode.

The light-emitting element 10 is placed on the protective element 20 with bumps B interposed therebetween. The bumps B can be, for example, plated bumps.

The protective element 20 includes a semiconductor substrate 24 including a protection circuit 243. The semiconductor substrate 24 includes a pair of connecting electrodes 21 provided on a surface of the semiconductor substrate 24 near the light-emitting element 10 to be electrically continuous with the light-emitting element 10, a pair of bottom electrodes 22 provided on a surface of the semiconductor substrate 24 near the mounting base to be electrically continuous with the base, and a pair of through-hole electrodes 23 for each connecting a corresponding one of the connecting electrodes 21 to a corresponding one of the bottom electrodes 22. The protective element 20 is encapsulated with a resin encapsulating part 25. The protective element 20 is, for example, a Zener diode.

The connecting electrodes 21 are provided on a mount surface 241 of the semiconductor substrate 24 on which an element is mounted, and include a cathode side electrode 211 connected to the cathode electrode 11 of the light-emitting element 10, and an anode side electrode 212 connected to the anode electrode 12 thereof. The connecting electrodes 21 are located to correspond to the cathode electrode 11 of the light-emitting element 10 and the anode electrode 12 thereof, and the light-emitting element 10 is mounted at a predetermined location. Thus, the connecting electrodes 21 are connected to the light-emitting element 10 so as to be electrically continuous with the light-emitting element 10.

As illustrated in FIG. 2, the cathode side electrode 211 is formed in a U shape along the edge of the semiconductor substrate 24. The anode side electrode 212 is provided on a central region of the semiconductor substrate 24 and a portion of an outer region thereof that are exposed from the U-shaped cathode side electrode 211. The location and shape of each of the cathode side electrode 211 and the anode side electrode 212 may be appropriately changed depending on the location and shape of a corresponding one of the cathode electrode 11 and the anode electrode 12 of the mounted light-emitting element 1.

As illustrated in FIG. 3, the bottom electrodes 22 are provided on a back surface 242 of the semiconductor substrate 24 opposite to the mount surface 241, and include a negative electrode 221 and a positive electrode 222. The negative electrode 221 and the positive electrode 222 are rectangular, and are located at one end of the back surface 242 of the semiconductor substrate 24, and the other end thereof, respectively. The location and shape of each of the bottom electrodes 22 may be appropriately changed depending on the location and shape of a corresponding one of electrodes on the mounting substrate 2 on which the semiconductor substrate 24 is mounted.

The through-hole electrodes 23 are located in four corresponding corner portions of the semiconductor substrate 24, and provides connection between the connecting electrodes 21 provided on the mount surface 241 and the bottom electrodes 22 provided on the back surface 242. The through-hole electrodes 23 include negative through-hole electrodes 231 connecting the cathode side electrode 211 to the negative electrode 221, and positive through-hole electrodes 232 connecting the anode side electrode 212 to the positive electrode 222.

The semiconductor substrate 24 is a rectangular silicon substrate. The semiconductor substrate 24 includes a p-type semiconductor region 2432 and an n-type semiconductor region 2431, and a protection circuit including, e.g., a Zener diode is formed in the surface of the semiconductor substrate 24. To form the semiconductor substrate 24, a plurality of p-type semiconductor regions 2432 and a plurality of n-type semiconductor regions 2431 may be formed in the surface of a silicon substrate at the wafer level, and then the silicon substrate may be singulated with a dicer.

The resin encapsulating part 25 is a resin, and is formed on the mount surface 241 of the semiconductor substrate 24. The resin encapsulating part 25 includes a first encapsulating part 251 and a second encapsulating part 252.

The first encapsulating part 251 covers the entire surface of the light-emitting element 10. The first encapsulating part 251 can be made of, for example, an optically transparent resin, such as a silicon resin or an epoxy resin. The first encapsulating part 251 may contain a fluorescent material emitting light excited by light from the light-emitting element 10 to undergo wavelength conversion.

Examples of the fluorescent material can include an yttrium aluminum garnet (YAG) fluorescent material and a silicate fluorescent material. When the fluorescent material is a material emitting light with a yellow color complementary to blue, the first encapsulating part 251 can emit light with a white color resulting from a mixture of blue and yellow. Furthermore, in order to provide higher color rendering of white light, a combination of a red fluorescent material and a green fluorescent material, or a combination of a red fluorescent material and a yellow fluorescent material can be used.

The second encapsulating part 252 covers the entire surface of the first encapsulating part 251. The second encapsulating part 252 is made of, for example, an optically transparent resin, such as a silicon resin or an epoxy resin, similarly to the first encapsulating part 251.

The first encapsulating part 251 can be formed, for example, by screen printing. When it is formed by screen printing, a printing plate having an opening at a location corresponding to the light-emitting element 10 may be disposed on the wafer-level semiconductor substrate 24 which has already included the protection circuit and the electrodes (the connecting electrodes 21, the bottom electrodes 22, and the through-hole electrodes 23) and on which the light-emitting element 10 has been mounted, and the opening may be filled with a resin material containing the fluorescent material. Shaping the first encapsulating part 251 as above enables the formation of the fluorescent material resin layer having a uniform thickness.

The entire surface of the wafer-level semiconductor substrate 24 including the first encapsulating part 251 is coated, and then the wafer-level semiconductor substrate 24 is singulated, thereby forming the second encapsulating part 252 that covers the first encapsulating part 251 and has a generally rectangular outer shape.

Since the light-emitting device of the embodiment configured as above includes the light-emitting element 10 placed on the protective element 20, the light-emitting element 10 is connected to a Zener diode ZD that is the protective element 20 in parallel as illustrated in FIG. 4.

In this embodiment, the protective element 20 is a Zener diode including the n-type semiconductor region 2431 and the p-type semiconductor region 2432. However, the protection circuit may be, for example, a diode or a varistor. Furthermore, this embodiment shows an example in which the light-emitting element 10 is placed on the protective element 20 to form a circuit including the light-emitting element 10 and the Zener diode ZD in parallel. However, the protective element 20 may include a Zener diode and a resistance element, and when the light-emitting element 10 is placed on the protective element 20, the resistance element may be connected to the light-emitting element 10 in series, and the light-emitting element 10 and the resistance element in series may be connected to the Zener diode in parallel.

The light-emitting device 1 mounted on the mounting substrate 2 as above does not require wiring from the protective element 20. Thus, after the protective element 20 on which the light-emitting element 10 is placed has been mounted on the mounting substrate 2, the light-emitting device 1 can be used without being entirely encapsulated with a resin. Thus, the light-emitting element 10 does not need to be encapsulated with a resin to protect a wire. This can reduce, for example, an encapsulation process step in a process of assembling parts into a product, thereby reducing the number of process steps and reducing cost.

Since the light-emitting device 1 includes the light-emitting element 10 placed on the mount surface 241 of the protective element 20, the light-emitting device 1 does not include a wire and other electrical components blocking the travel of light from the light-emitting element 10. This enables uniform irradiation of a surrounding region with the light from the light-emitting element 10. This uniform irradiation allows the light-emitting device 1 to be downsized and to function as a point source.

While the semiconductor substrate 24 here is exemplarily a silicon substrate, the semiconductor substrate 24 is not limited to the silicon substrate. However, since the silicon substrate is less likely to be curved than, for example, a ceramic substrate, and has high flatness, the first encapsulating part 251 is less likely to be curved, and tends to have a uniform thickness. This allows the concentration of the fluorescent material to be uniform, and reduces color shading called a yellow ring. This can reduce variations in chromaticity of the first encapsulating part 251.

Silicon has higher thermal conductivity than, for example, ceramic (Al₂O₃, low temperature co-fired ceramic (LTCC)). Thus, when the semiconductor substrate 24 is a silicon substrate, heat from the light-emitting element 10 can be efficiently transferred through the semiconductor substrate 24 and the bottom electrodes 22 to the mounting substrate 2. This also reduces degradation of the light-emitting element 10.

Each of the pair of the connecting electrodes 21 and a corresponding one of the pair of the bottom electrodes 22 can be connected together through a side electrode formed on a side surface of the semiconductor substrate 24. However, since the through-hole electrodes 23 can be formed in the wafer-level the semiconductor substrate 24 that has not been singulated yet, this eliminates the need for process steps, such as the step of plating the semiconductor substrate 24 after the semiconductor substrate 24 has been singulated, and facilitates fabrication.

While, in this embodiment, a lighting device for an electronic flash of a mobile phone was described, the light-emitting device of the present disclosure can be similarly used also as other lighting devices. While the mounting substrate was used as the mounting base, the light-emitting device may be mounted on, for example, a lead frame instead of the mounting substrate.

### INDUSTRIAL APPLICABILITY

The light-emitting device of the present disclosure protects a light-emitting element, enables uniform irradiation of a surrounding region with light from the light-emitting element, and can be downsized. Thus, the present disclosure is suitable for a protective element on which a light-emitting element is placed, and which is connected to the light-emitting element in parallel to protect the light-emitting element from high voltages, such as static electricity, and a light-emitting device including the same.

### DESCRIPTION OF REFERENCE CHARACTERS

1 LIGHT-EMITTING DEVICE
2 MOUNTING SUBSTRATE
2a, 2b INTERCONNECT TRACE
10 LIGHT-EMITTING ELEMENT
11 CATHODE ELECTRODE
12 ANODE ELECTRODE
20 PROTECTIVE ELEMENT
21 CONNECTING ELECTRODE
22 BOTTOM ELECTRODE
23 THROUGH-HOLE ELECTRODE
24 SEMICONDUCTOR SUBSTRATE
25 RESIN ENCAPSULATING PART
211 CATHODE SIDE ELECTRODE
212 ANODE SIDE ELECTRODE
221 NEGATIVE ELECTRODE
222 POSITIVE ELECTRODE
231 NEGATIVE THROUGH-HOLE ELECTRODE
232 POSITIVE THROUGH-HOLE ELECTRODE
241 MOUNT SURFACE
242 BACK SURFACE
243 PROTECTION CIRCUIT
251 FIRST ENCAPSULATING PART
252 SECOND ENCAPSULATING PART
2431 N-TYPE SEMICONDUCTOR REGION
2432 P-TYPE SEMICONDUCTOR REGION
B BUMP
ZD ZENER DIODE

1. A protective element comprising:
a semiconductor substrate;
connecting electrodes provided on a mount surface of the semiconductor substrate on which a light-emitting element for flip-chip mounting is mounted so as to be each connected to an electrode of the light-emitting element;
a protection circuit provided in the semiconductor substrate so as to be connected through the connecting electrodes to the light-emitting element; and
bottom electrodes provided on a surface of the semiconductor substrate opposite to the mount surface, each connected to a corresponding one of the connecting electrodes, and configured so as to be each connected to an electrode on a mounting base.

2. The protective element of claim 1 further comprising:
through-hole electrodes each connecting a corresponding one of the connecting electrodes to a corresponding one of the bottom electrodes.

3. The protective element of claim 1, wherein
the semiconductor substrate is a silicon substrate.

4. The protective element of claim 1, wherein
the protection circuit includes a Zener diode, a diode, or a varistor.

5. A light-emitting device comprising:
the protective element of claim 1;
the light-emitting element incorporated into the protective element; and
a resin encapsulating part that contains a fluorescent material excited by light from the light-emitting element to emit light, and encapsulates the light-emitting element.
